(19) United States
(12) Patent Application Publication
(10) Pub. No.: US 2014/0218637 A1
(43) Pub. Date: Aug. 7, 2014

(54) CONDUCTIVE FILM, MANUFACTURING METHOD THEREOF, AND TOUCH SCREEN INCLUDING THE CONDUCTING FILM

(71) Applicants: Yulong Gao, Jiangxi 330013 (CN); Zheng Cui, Jiangsu 215123 (CN); Chao Sun, Jiangxi 330013 (CN)

(72) Inventors: Yulong Gao, Jiangxi 330013 (CN); Zheng Cui, Jiangsu 215123 (CN); Chao Sun, Jiangxi 330013 (CN)

(73) Assignee: NANCHANG O-FILM TECH. CO., LTD., JIANGXI (CN)

(21) Appl. No.: 14/000,526

(22) PCT Filed: Jul. 6, 2013
(86) PCT No.: PCT/CN2013/078945

§ 371 Date: Aug. 20, 2013

(30) Foreign Application Priority Data
Feb. 6, 2013 (CN) 201310048682.9

(51) Int. Cl. H05K 1/02; H05K 3/46

(52) U.S. Cl. CPC H05K 1/0298; H05K 3/4664
USPC 349/12; 174/251; 428/213; 427/97.4

(57) ABSTRACT

A conductive film includes a substrate, a first conductive layer, a matrix layer, and a second conductive layer. The substrate includes a first surface and an oppositely arranged second surface. The first conductive layer is embedded in the substrate. The matrix layer is set on the first surface of the substrate. The matrix layer is formed by solidified jelly coating. The second conductive layer embedded in the matrix layer. The second conductive layer is insulated from the first conductive layer. Due to the capacitor formed between the first conductive layer and the second conductive layer, it just needs to attach the conductive film to a glass panel when the conductive film is adopted to manufacture a touch screen, without bonding two pieces of conductive films. In addition, the matrix layer, formed by solidifying the jelly painted on the substrate, is with a much smaller thickness than the substrate. Therefore, the touch screen using the conductive film has a smaller thickness. In addition, a method of manufacturing the conductive film and a touch screen including the conductive film are also provided by the present disclosure.

### FIELD OF THE INVENTION

The present disclosure relates to electronic technology, and more particularly relates to a conductive film, method of manufacturing the conductive film, and a touch screen including the conductive film.

### BACKGROUND OF THE INVENTION

Conductive film is a kind of film with good electrical conductivity and flexibility, which for now is mainly applied in touch screen filed and etc., and has great market space. A traditional conductive film comprises a substrate and a conductive layer formed on the substrate. The conductive layer is formed on the substrate by coating, spraying, or other process. When this kind of conductive film is used in practical application, two pieces of conductive films are attached together with adhesive for special usage, such as electromagnetic screen film, touch-sensitive film, and etc.

For example, in touch screen of mobile phone, two pieces of conductive films are attached together with optically transparent adhesive. A specific area of a conductive film is overlapped with a specific area of the other conductive film, forming a structure similar to a capacitor. When one of the conductive films is approached by a finger or a touch-controlled pen, capacity variation of the overlapped area is thereby caused to implement perception of the touch position and performance of touch instruction.

According to the above-mentioned, the traditional conductive film needs to be attached together with two pieces after forming, before practical application. Due to the thickness of the substrate and the thickness of the transparent adhesive, the traditional conductive film result in the touch screen with a relatively greater thickness, that is unfavorable to lightening and thinning development of electronic products.

### SUMMARY OF THE INVENTION

The invention present disclosure is directed to provide a conductive film which effectively reduces thickness of touch screen, a method of manufacturing the conductive film, and a touch screen including the conductive film.

According to an aspect of the present disclosure, a conductive film is provided, which includes:

a substrate comprising a first surface and a second surface opposite to the first surface;

a first conductive layer embedded in the substrate, a thickness of the first conductive layer being smaller than that of the substrate;

a matrix layer disposed on a first surface of the substrate, the matrix layer being made of a solidified jelly coating, a thickness of the matrix layer being smaller than the thickness of the substrate; and

a second conductive layer embedded in the matrix layer, a thickness of the second conductive layer being smaller than that of the matrix layer, the second conductive layer being insulated from the first conductive layer.

In a preferred embodiment, first grooves are defined in the first surface, second grooves are defined in a side of the matrix layer away from the substrate, and the first conductive layer and the second conductive layer are respectively received in the first grooves and the second grooves.

In a preferred embodiment, a distance between the first conductive layer and the second conductive layer is less than the thickness of the substrate, the thickness of the first conductive layer is no greater than a depth of the first groove, and the thickness of the second conductive layer is no greater than a depth of the second groove.

In a preferred embodiment, the first conductive layer and the second conductive layer are both conductive meshes consists of crisscross conductive wires, the conductive meshes comprise a plurality of grid units, the conductive wires of the first conductive layer are received in the first grooves, the conductive wires of the second conductive layer are received in the second grooves, and width of the conductive wires ranges between 500 nm and 5 μm.

In a preferred embodiment, the conductive wire is made of a material selected from the group consisting of metal, conductive polymer, grapheme, carbon nano-tube, and ITO.

In a preferred embodiment, the metal is selected from the group consisting of Au, Ag, Cu, Al, Ni, Zn, and an alloy of at least two of them.

In a preferred embodiment, the grid units are rhomboic, rectangle, parallelogram, or curved quadrilateral, and projection of centers of the grid units of the second conductive layer on the first conductive layer are spaced centers of the corresponding grid units of the first conductive layer.

In a preferred embodiment, distances between the projection of the center of the grid units of the second conductive layer on the first conductive layer and the centers of the corresponding grid units of the first conductive layer ranges from 1/3a to \sqrt{2}a/2, wherein “a” is a length of a side of one of the grid units.

In a preferred embodiment, projections of lines connecting centers of the grid units of the second conductive layer arranged in a direction on the first conductive layer is misaligned with lines connecting centers of the grid units of the first conductive layer in the same direction.

In a preferred embodiment, the conductive film further includes:

a tackifier layer located between the substrate and the matrix layer, for adhering the matrix layer to the substrate; and

a functional attached to the second surface, for protection and anti-reflection.

In a preferred embodiment, the conductive film further comprises a first electrode lead cluster and a second electrode lead cluster, the first electrode lead cluster being embedded in the substrate and electrically connected to the first conductive layer, and the second electrode lead cluster being embedded in the matrix layer and electrically connected to the second conductive layer.

In a preferred embodiment, the first conductive layer comprises a plurality of mutually-insulated first gird strips, the second conductive layer comprises a plurality of mutually-insulated second gird strips, the first electrode lead cluster comprises a plurality of first leads respectively electrically connected to the first grid strips, and the second electrode lead cluster comprises a plurality of second leads respectively electrically connected to the second grid strips.

In a preferred embodiment, a first strip-like connecting portion is provided at the end of each of the first electrode leads near to the first conductive layer, the first connecting portion is thicker than other portion of the first electrode lead, a second strip-like connecting portion is provided at the end of each of the second electrode leads near to the second conductive layer, and the second connecting portion is thicker than other portion of the second electrode lead.

In a preferred embodiment, the first electrode lead and the second electrode lead consists of metal wires, which is crisscross to forming, and grid range of the first electrode lead and the second electrode lead is less than that of the first conductive layer and the second conductive layer.

In a preferred embodiment, a first electrode switching line is provided between each of the first electrode lead and the first conductive layer, a second electrode switching line is provided between each of the second electrode lead and the second conductive layer, the first switching line and the second switching line are consecutive fine conductive wires, the first switching line is connected to ends of at least two conductive wires of the first conductive layer and ends of at least two conductive wires of the first electrode lead, and the second switching line is connected to ends of at least two conductive wires of the second conductive layer and ends of at least two conductive wires of the second electrode lead.

According to an aspect of the present disclosure, another touch screen is provided, which includes:

a glass panel; and

a conductive film comprising:

a substrate comprising a first surface and an second surface opposite to the first surface;

a first conductive layer embedded in the substrate, a thickness of the first conductive layer being smaller than that of the substrate;

a matrix layer disposed on a first surface of the substrate, the matrix layer being made of a solidified jelly coating, a thickness of the matrix layer being smaller than the thickness of the substrate; and

a second conductive layer embedded in the matrix layer, a thickness of the second conductive layer being smaller than that of the matrix layer, the second conductive layer being insulated from the first conductive layer.

A method of manufacturing touch screen includes the steps of:

providing a substrate, the substrate comprising a first surface and a second surface opposite to the first surface, and defining first grooves in the first surface;

filling conductive material into the first grooves to form a first conductive layer;

painting jelly on the first surface, solidifying the jelly to form a matrix layer, and defining a second groove in the matrix layer; and

filling conductive material into the second groove to form a second conductive layer.

In a preferred embodiment, a first electrode lead cluster electrically connected to the first conductive layer is formed while filling conductive material into the first groove to form the first conductive layer, and a second electrode lead cluster electrically connected to the second conductive layer is formed while filling conductive material into the second groove to form the second conductive layer.

In a preferred embodiment, the first conductive layer and the second conductive layer are conductive meshes consists of crisscross conductive wires, the conductive meshes comprise a plurality of grid units, the conductive wires of the first conductive layer are received in the first grooves, the conductive wires of the second conductive layer are received in the second groove, grid range of the first electrode lead and the second electrode lead is less than that of the first conductive layer and the second conductive layer.

In a preferred embodiment, a first electrode switching line is provided between each of electrode lead of the first electrode lead cluster and the first conductive layer, a second electrode switching line is provided between each of electrode lead of the second electrode lead cluster and the second conductive layer, the first switching line and the second switching line are consecutive fine conductive wires, the first switching line is connected to ends of at least two conductive wires of the first conductive layer and ends of at least two conductive wires of the first electrode lead, and the second switching line is connected to ends of at least two conductive wires of the second conductive layer and ends of at least two conductive wires of the second electrode lead.

Comparing to the traditional film, the conductive film is superior in at least the following aspects.

Firstly, the conductive film has two opposite conductive layers, which are respectively the first conductive layer and the second conductive layer. Due to the capacitor formed between the first conductive layer and the second conductive layer, it just needs to attach the conductive film to a glass panel when the conductive film is adopted to manufacture a touch screen, without bonding two pieces of conductive films. In addition, the matrix layer, formed by solidifying the jelly painted on the substrate, is with a much smaller thickness than the substrate. Therefore, a touch screen using the conductive film has a smaller thickness.

Secondly, no bonding process is needed when the conductive film is adopted to manufacture a touch screen. Therefore, introducing impurities during bonding, and affecting appearance and performance of the touch screen are avoided. Moreover, it simplifies the process and improves the manufacturing efficiency, using the conductive film to manufacturing a touch screen.

### BRIEF DESCRIPTION OF THE DRAWINGS

FIG. 1 is a schematic view of a preferred embodiment of a touch screen according to the present disclosure.

FIG. 2 is a schematic view of layers of the touch screen in FIG. 1.

FIG. 3 is a schematic view of layers of the conductive film in FIG. 2.

FIG. 4 is a schematic view of the conductive film in FIG. 2.

FIG. 5 is a schematic view of the conductive film in FIG. 2, in another aspect.

FIG. 6 is a partially-enlarged schematic view of the first conductive layer of the conductive film in FIG. 2.

FIG. 7 is a partially-enlarged schematic view of the second conductive layer of the conductive film in FIG. 2.

FIG. 8 is a partially-enlarged schematic view of a first electrode lead and a second electrode lead of a conductive film according to another preferred embodiment of the present disclosure.

FIG. 9 is a schematic flow chart of an embodiment of a method of manufacturing a conductive film.

FIG. 10 is a schematic flow diagram of an embodiment of a method of manufacturing a conductive film.

FIG. 11 is a schematic flow diagram of an embodiment of a method of forming electrode leads.

### DETAILED DESCRIPTION OF THE EMBODIMENTS

The invention is described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete.

It should be noted that, when an element is described as “fixed to” another element, it means the element can be fixed to another element directly or with a middle element. When an element is described as “connected to” another element, it means the element can be connected to another element directly or with a middle element.

Unless defined elsewhere, all the technology and science terms used herein should be with the same meaning as understood by those skilled in the art. All the terms used herein are just for the purpose of describing detailed embodiments, but not limited to the scope of the present disclosure. All the “and / or” used herein comprises one listed item, or any combination of more related listed items.

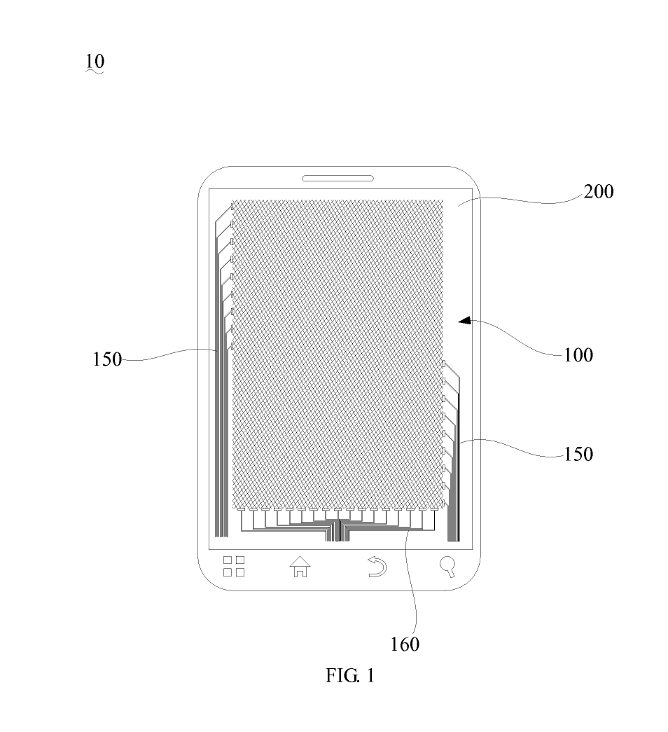

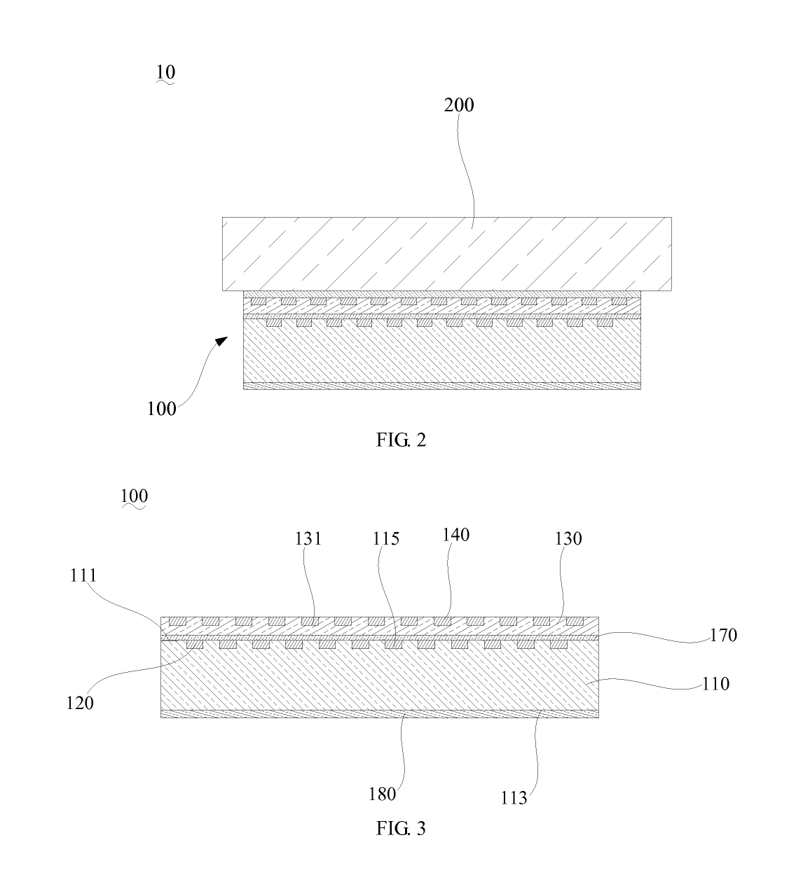

Referring to FIG. 1 and FIG. 2, a touch screen 10 according to a preferred embodiment of the present disclosure comprises a conductive film 100 and a glass panel 200. The conductive film 100 is attached to the glass panel 200.

Referring to FIG. 3 together, the conductive film 100 comprises a substrate 110, a first conductive layer 120, a matrix layer 130, a second conductive layer 140, a first electrode lead 150, a second electrode lead 160, a tackifier layer 170, and a functional layer 180.

The substrate 110 comprises a first surface 111 and a second surface 113, the first surface 111 and the second surface 113 being oppositely arranged. In the present embodiment, the substrate 110 is a film of insulating material polyethylene terephthalate (PET). What should be pointed out is, in other embodiment, the substrate 110 may be a film of other material, such as polybutylene terephthalate (PBT), polymethylmethacrylate (PMMA), polycarbonate (PC), glass, and etc. When the conductive film 100 is applied to manufacturing of a touch screen, the material for the substrate 110 is optimal to be transparent insulating material.

The first conductive layer 120 is embedded in the first surface 111 of the substrate 110. The thickness of the first conductive layer 120 is less than that of the substrate 110. The substrate 110 prevents the first conductive layer 120 from being damaged in the subsequent process. Further, the first surface 111 has relatively small concaves and convexes, which makes subsequent coating easier. In the present embodiment, the first surface 111 defines a first groove 115 with depth larger than the thickness of the first conductive layer 120. The first conductive layer 120 is received in the first groove 115. In other embodiment, the thickness of the first conductive layer 120 can be equal to the depth of the first groove 115.

The first conductive layer 120 is a conductive grid constructed by inter-crossed metal wires. The conductive grid has a plurality of grid units. In the present embodiment, the linewidth of the metal wires ranges between 500 nm and 5 μm. Herein, the grid units of the first conductive layer 120 are first grid units 121. What should be pointed out is, in other embodiment, the first conductive layer 120 is not limited to the conductive grid constructed by inter-crossed metal wires, and may be wires of other conductive material, such as conductive polymer, grapheme, carbon nano-tube, indium tin oxide (ITO), and etc.

The matrix layer 130 is attached to the first surface 111 of the substrate 110. The matrix layer 130 is formed by solidifying the jelly painted on the first surface 111, and is thus with a smaller thickness than that of the substrate 110. The matrix layer 130 is made from transparent insulating material which is different from the material of the substrate 110. Specifically, a side beyond the substrate 110 of the matrix layer 130 is bonding to the glass panel 200, to make the conductive film 100 be attached to the glass panel 200.

In the present embodiment, the jelly for forming the matrix layer 130 is solvent-free UV-curing acrylic resin. In other embodiment, the jelly for forming the matrix layer 130 may be other light-curing adhesive, heat-curing adhesive, and self-curing adhesive. Herein, the light-curing adhesive may be a mixture of prepolymer, monomer, photoinitiator, and additive, in molar ration of 30˜50%, 40˜60%, 1˜6%, and 0.2˜1%. Herein, the prepolymer is at least one of epoxy acrylate, polyurethane acrylate, polyether acrylates, polyester acrylate, and acrylic resin; the monomer is at least one of monofunctional (IBOA, IBOMA, HEMA, and etc.), bifunctional (TPGDA, HDDA, DEGDA, NPGDA and etc.), trifunctional, and multifunctional (TMPTA, PETA and etc.); the photoinitiator is benzophenone, desoxybenzoin, or etc. Furthermore, additive in molar ration of 0.2˜1% can be added into the mixture. The additive may be hydroquinone, or p-methoxyphenol, or benzoquinone, or 2,6-di-tert-butyl -cresol, or etc.

The second conductive layer 140 is embedded in the matrix layer 130. The thickness of the second conductive layer 140 is less than that of the matrix layer 130. The matrix layer 130 prevents the second conductive layer 140 from being damaged in the subsequent process. Further, the matrix layer 130 has relatively small concaves and convexes, which makes subsequent coating and attaching process easier. The second conductive layer 140 and the first conductive layer 130 are separated by the matrix layer 130, to make the first conductive layer 130 and the second conductive layer 140 insulated from each other, forming a structure similar to a capacitor. In addition, the spacing distance between the first conductive layer 120 and the second conductive layer is less than the thickness of the substrate 110.

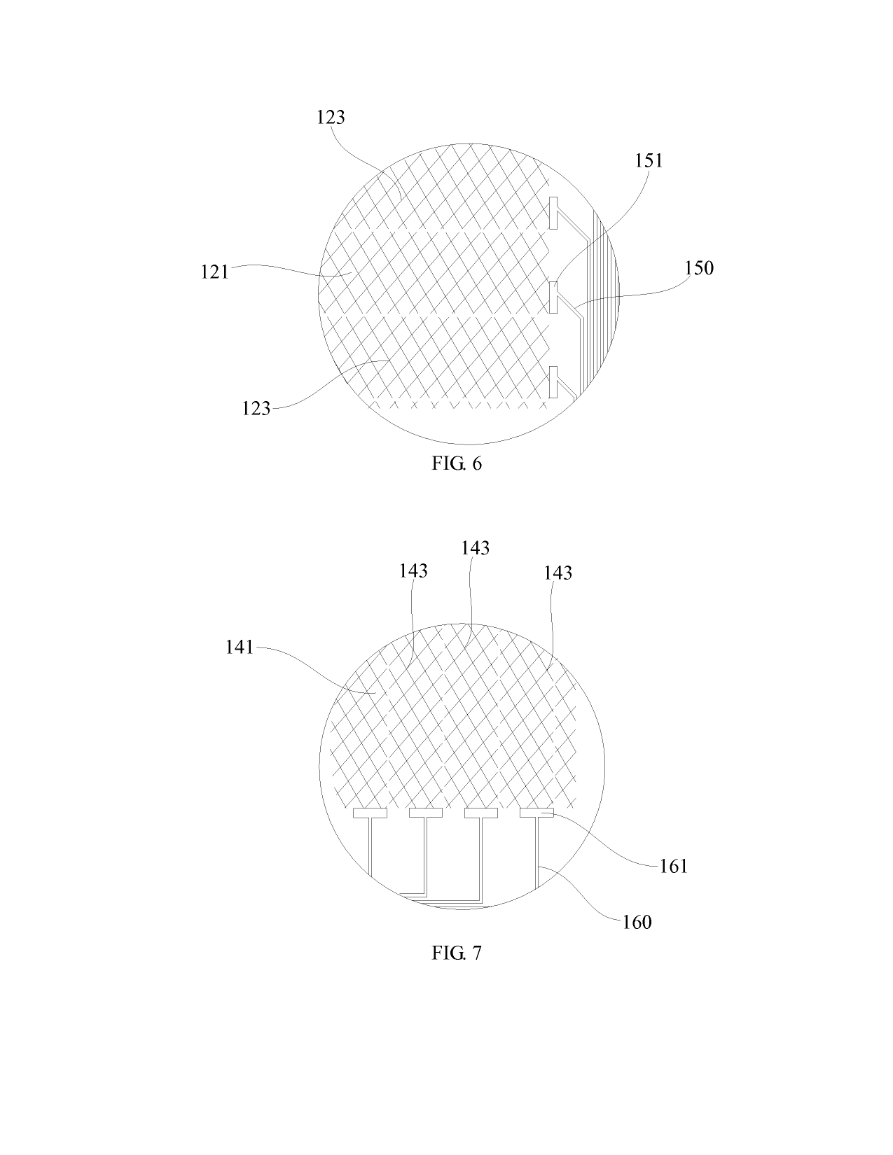

Referring FIG. 6 and FIG. 7 together, in the present embodiment, a second groove 131 is defined on a side beyond the substrate 110 of the matrix layer 130. The depth of the second groove 131 is larger than the thickness of the second conductive layer 140. The second conductive layer 140 is received in the second groove 131. Specifically, the second conductive layer 140 is a conductive grid constructed by inter-crossed metal wires. The conductive grid has a plurality of grid units. Herein, the grid units of the second conductive layer 140 are second grid units 141. What should be pointed out is, in other embodiment, the second conductive layer 140 is not limited to the conductive grid constructed by inter-crossed metal wires, and may be wires of other conductive material, such as conductive polymer, grapheme, carbon nano-tube, ITO (Indium Tin Oxide), and etc. In other embodiment, the thickness of the second conductive layer 140 can be equal to the depth of the second groove 131.

Moreover, in the embodiment, material for making the first conductive layer 120 and the second conductive layer 140 can be one of Au, Ag, Cu, Ni, Al, and Zn, or alloy of at least two of them. It can be understood that, the material for making the first conductive layer 120 and the second conductive layer 140 is electrically conductive to implement corresponding function.

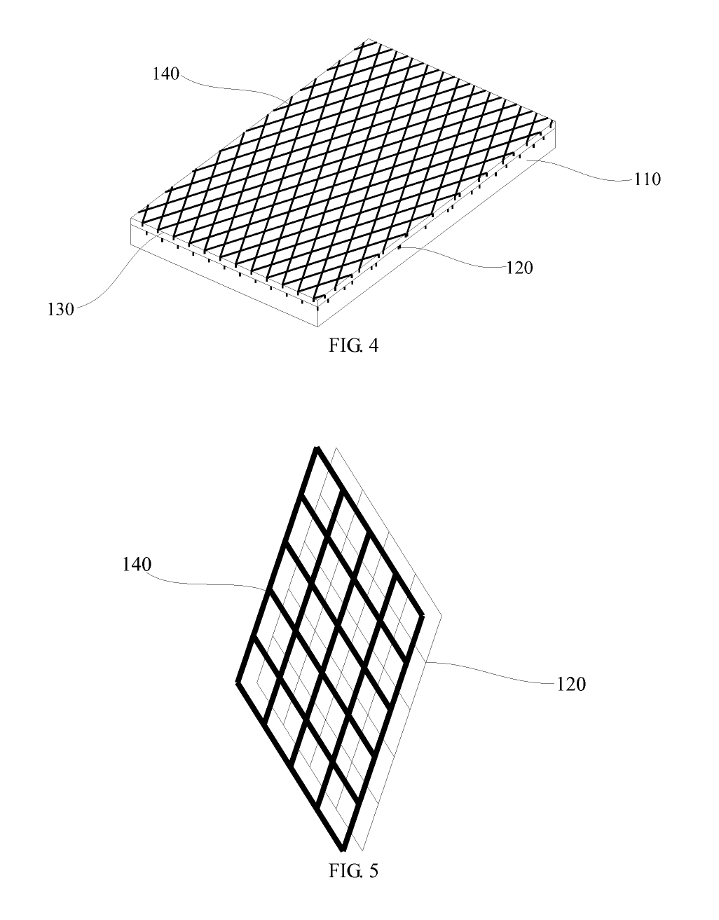

Referring to FIG. 4 and FIG. 5 together, in the present embodiment, the grid units are rhombic. The center of the grid units of the second conductive layer 140 is projected on the first conductive layer 120, with the projection spaced a predetermined distance from the center of the grid units of the first conductive layer 120. Specifically in the present embodiment, the predetermined distance ranges between 1/3a and \sqrt{2}a/2, where “a” is the side length of the grid units. Therefore, the conductive wires constructing the first conductive layer 120 and the second conductive layer 140 are deviated from each other for a certain distance, to avoid serious Moire phenomenon while the conductive film 100 used in an LCD monitor. In other embodiment, the grid may also be rectangle, or parallelogram, or curved quadrilateral with four curved sides, two opposite sides of which are in the same shape and with the same curve trend.

Furthermore, connecting lines of centers of the second grid units 141 in the same arrangement direction of the second conductive layer 140 are projected on the first conductive layer 120, with the projection misalign with connecting lines of centers of the first grid units 121 in the same arrangement direction of the first conductive layer 120. Moire phenomenon is thus further reduced.

The first electrode lead 150 is embedded in the substrate 110, and electrically connected to the first conductive layer 120. When the conductive film 100 is used to manufacture a touch screen of an electronic device, the first electrode lead 150 is used to electrically connect the first conductive layer 120 and the electronic device, thus enabling the controller to sense operation of the touch screen. In the present embodiment, the first electrode lead 150 is a single solid line. A notch for receiving the first electrode lead 150 is defined in the substrate 110. The first electrode lead 150 is received in the notch. The substrate 110 acts as both a forming carrier and a protective layer of the first electrode lead 150. Furthermore, a first connecting portion 151 is formed on the first electrode lead 150. The first connecting portion 151 is located on an end near to the first conductive layer 120. The first connecting portion 151 has a greater width than other portion of the first electrode lead 150 with thus a larger contacting area, so that it is easier for the first electrode lead 150 to electrically connect to conductive wires of the first conductive layer 120.

The second electrode lead 160 is embedded in the matrix layer 130, and electrically connected to the second conductive layer 140. When the conductive film 100 is used to manufacture a touch screen of an electronic device, the second electrode lead 160 is used to electrically connect the second conductive layer 140 and the electronic device, thus enabling the controller to sense operation of the touch screen. In the present embodiment, the second electrode lead 160 is a single solid line. A notch for receiving the second electrode lead 160 is defined in the substrate 110. The second electrode lead 160 is received in the notch. The substrate 110 acts as both a forming carrier and a protective layer of the second electrode lead 160. Furthermore, a second connecting portion 161 is formed on the second electrode lead 160. The second connecting portion 161 is located on an end near to the second conductive layer 140. The second connecting portion 161 has a greater width than other portion of the second electrode lead 160 with thus a larger contacting area, so that it is easier for the second electrode lead 160 to electrically connect to conductive wires of the second conductive layer 140.

Referring to FIG. 6, in another embodiment, the first electrode lead 150 and the second electrode lead 160 are constructed by mesh-intersecting conductive wires. The first electrode lead 150 and the second electrode lead 160 respectively have a consecutive first electrode switching line 153 and a consecutive second electrode switching line 163. The grid range of the first electrode lead 150 and the second electrode lead 160 is different from the gird cycle of the first conductive layer 120 and the second conductive layer 140, wherein the grid range means the size of the grid unit. The grid range of the first electrode lead 150 and the second electrode lead 160 is less than that of the first conductive layer 120 and the second conductive layer 140. Therefore, it may be difficult to align when the first electrode lead 150 and the second electrode lead 160 electrically connect to the first conductive layer 120 and the second conductive layer 140. The first connecting portion 151 and the second connecting portion 161 are connected to the first conductive layer 120 and the second conductive layer 140 respectively via the first electrode switching line 151 and the second electrode switching line 161. The first electrode switching line 151 and the second electrode switching line 161 are consecutive metal wires, so that, the first electrode switching line 151 can connect to ends of at least two conductive wires of the first conductive layer 120 and the first electrode lead 150, and the second electrode switching line 161 can connect to ends of at least two conductive wires of the second conductive layer 140 and the second electrode lead 160. Therefore, the first electrode switching line 151 and the second electrode switching line 161 can resolve the problem of aligning difficulty of conductive wires in different grid ranges, thus making it easier for the first electrode lead 150 and the second electrode lead 160 to electrically connect to the first conductive layer 120 and the second conductive layer 140.

In order to highlight the first electrode switching line 153 and the second electrode switching line 163 in the figure, the first electrode switching line 153 and the second electrode switching line 163 are shown with a larger line width than the conductive wires of the first electrode lead 150 and the second electrode lead 160. It should not understood as that, the first electrode switching line 153 and the second electrode switching line 163 are of a larger thickness than the conductive wires constructed the first electrode lead 150 and the second electrode lead 160. The thickness of the first electrode switching line 153 and the second electrode switching line 163 can be determined according to application environment in practical application.

What should be pointed out is, the first electrode lead 150 and the second electrode lead 160 can be omitted in other embodiment. When manufacturing touch screen, external leads can be adopted to extract the first conductive layer 120 and the second conductive layer 140.

In the present embodiment, the first conductive layer 120 can be divided into a plurality of mutually-insulated first gird strips 123, and the second conductive layer 140 can be divided into a plurality of mutually-insulated second gird strips 143. The first electrode lead 150 includes a plurality of leads electrically connected to the first gird strips 123 respectively. The second electrode lead 160 includes a plurality of leads electrically connected to the second grid strips 143 respectively. Specifically, the conductive wires of the first conductive layer 120 are cut off in a particular direction, forming a plurality of parallel first grid strips 123. The first grid strips 123 may be used as driving grid strip in practical application. The conductive wires of the second conductive layer 140 are cut off in a particular direction, forming a plurality of parallel second grid strips 143. The second grid strips 143 may be used as sensing grid strip in practical application.

The tackifier layer 170 is located between the substrate 110 and the matrix layer 130. The tackifier layer 170 is used to connect the substrate 110 and the matrix layer 130. The tackifier layer 170 is formed by adhesive painted on the first surface 111, so the tackifier layer 170 plays the role of increasing adhesive strength between the matrix layer 130 and the substrate 110. In the present embodiment, the adhesive for forming the tackifier layer 170 can be one of epoxy resin, epoxy silane, and polyimide resin.

The functional layer 180 is attached to the second surface 113. The functional layer 180 plays the role of protection and anti-reflection. The functional layer 180 includes a portion of hardening function and a portion of anti-reflection function. The portion of hardening function is formed by coating polymer coating with hardening function. The portion of anti-reflection function is titania cladding, or magnesium fluoride coating, or Calcium fluoride cladding.

What should be pointed out is, the tackifier layer 170 and the functional layer 180 can be omitted in other embodiment.

Comparing to the traditional film, the conductive film 100 is superior in at least the following aspects.

Firstly, the conductive film 100 has two opposite conductive layers, which are respectively the first conductive layer 120 and the second conductive layer 140. Due to the capacitor formed between the first conductive layer 120 and the second conductive layer 140, it just needs to attach the conductive film 100 to the glass panel 200, without bonding two pieces of the conductive films. In addition, the matrix layer 130, formed by solidifying the jelly painted on the substrate 110, is with a much smaller thickness than the substrate 110. Therefore, a touch screen 10 using the conductive film 100 has a smaller thickness.

Secondly, no bonding process is needed when the conductive film 100 is adopted to make the touch screen 10. Therefore, introducing impurities during bonding, and affecting appearance and performance of the touch screen 100 is the avoided. Moreover, it simplifies the process and improves the manufacturing efficiency, using the conductive film 100 to manufacturing the touch screen 10.

In addition, a method for manufacturing a conductive film is also provided by the present disclosure.

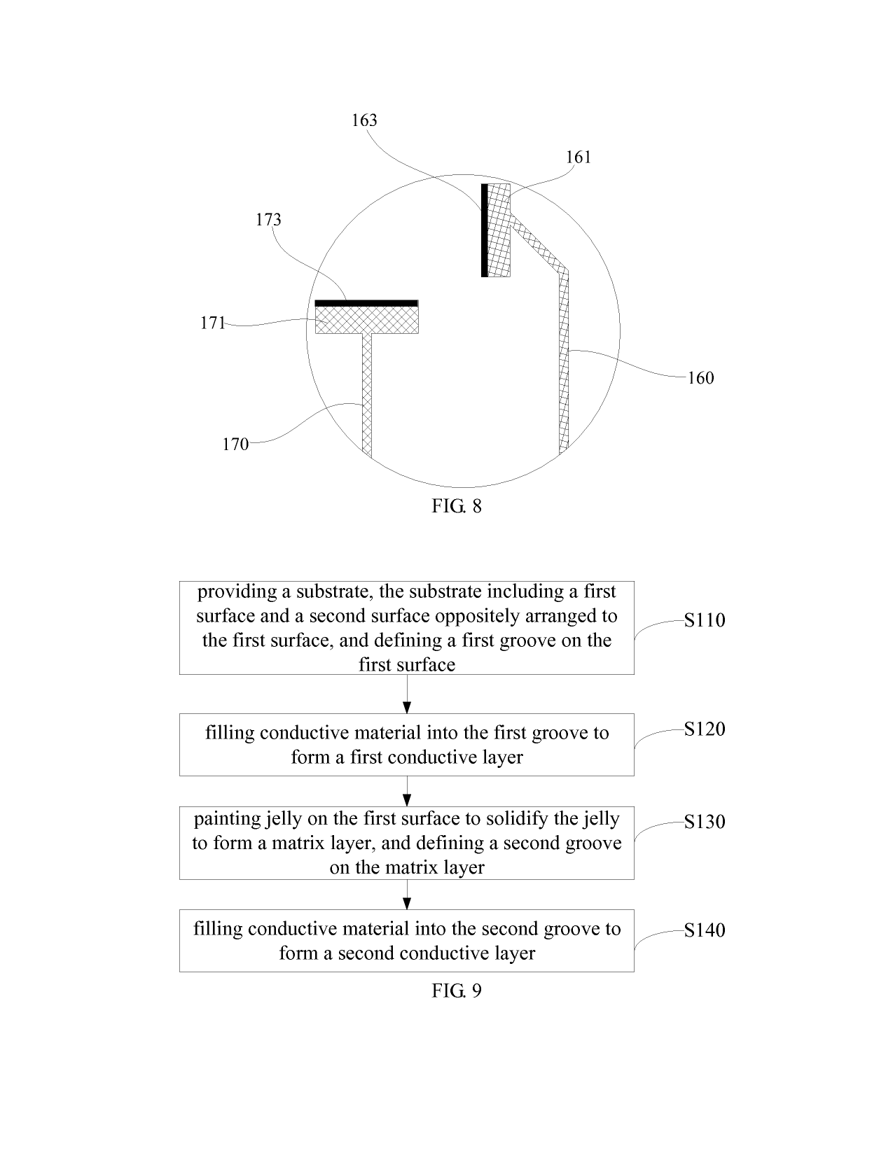

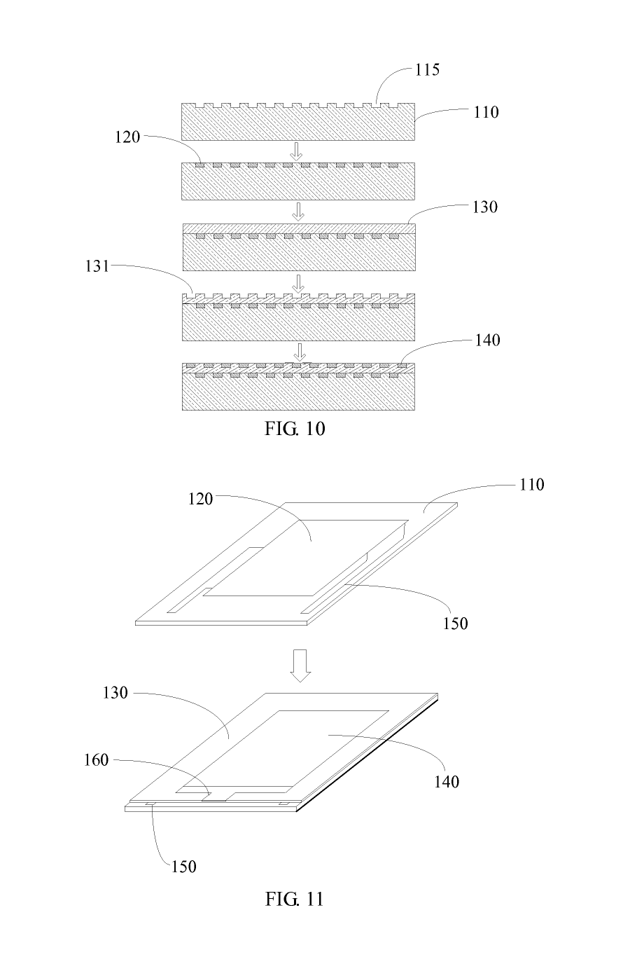

Referring to FIG. 9 and FIG. 10, a method for manufacturing a conductive film according to an embodiment includes steps S110˜S140.

In step S110, a substrate 110 including a first surface and an oppositely arranged second surface is provided. The first groove 115 is defined on the first surface.

In the present embodiment, the material of the substrate 110 is polyethylene terephthalate (PET). What should be pointed out is, in other embodiment, the material of the substrate 110 may be other material, such as polybutylene terephthalate (PBT), polycarbonate (PC) plastic, and glass. Specifically in the present embodiment, the depth of the substrate 110 is 125 micrometers. In addition, the first groove 115 is formed on the first surface by imprinting, with the depth of 3 micrometers and the width of 2.2 micrometers.

What should be pointed out is, the parameters of the substrate 110 and the first groove 115 are ones among preferred embodiments, and the depth and width of the substrate 110 can be changed according to actual needs.

In step S120, conductive material is filled in the first groove 115 to form the first conductive layer 120.

In the present embodiment, the first groove 115 is in the shape of grid, and the conductive material forms intertwined conductive wires in the first groove 115, constructing a conductive grid. Specifically, nano silver ink is filled in the first groove 115 by scrapping technology, and is then sintered in the condition of 150 to make elemental silver of the nano silver ink be sintered into conductive wires. Herein, solid content of the silver ink is 35%, and the solvent is volatilized during sintering.

Referring also to FIG. 9, in the present embodiment, the step S120 also includes forming the first electrode lead 150 electrically connected to the first conductive layer 120.

Specifically in the present embodiment, the first groove 115 includes a groove for receiving the first electrode lead 150. When filling conductive material into the first groove 115, the conductive material forms the first electrode lead 150 in the groove for receiving the first electrode lead 150.

In step S130, jelly is painted on the first surface and is solidified to form the matrix layer 130, and the second groove 131 is defined on the matrix layer 130.

In the present embodiment, the jelly painted on the first surface is solvent-free UV-curing acrylic resin. In addition, the matrix layer 130 is not completely covering the first electrode lead 150, to expose the free end of the first electrode lead 150. In other embodiment, the jelly may be light-curing adhesive, or heat-curing adhesive, or self-curing adhesive. Herein, the light-curing adhesive may be a mixture of prepolymer, monomer, photoinitiator, and additive, in molar ration of 30˜50%, 40˜60%, 1˜6%, and 0.2˜1%. Herein, the prepolymer is at least one of epoxy acrylate, polyurethane acrylate, polyether acrylates, polyester acrylate, and acrylic resin; the monomer is at least one of monofunctional, bifunctional, trifunctional, and multifunctional; the photoinitiator is benzophenone, desoxybenzoin, or etc. Furthermore, the additive in molar ration of 0.2˜1% can be added into the mixture. The additive may be hydroquinone, or p-methoxyphenol, or benzoquinone,or 2,6-di-tert-butyl -cresol, or etc.

Further, the second groove 131 is formed on the side beyond the substrate 110 of the matrix layer 130 by imprinting. Specifically, the depth of the second groove 131 is 3 micrometers, and the width is 2.2 micrometers.

In step S140, conductive material is filled in the second groove 131 to form the second conductive layer 140.

In the present embodiment, the second groove 131 is in the shape of grid, and the conductive material forms intertwined conductive wires in the second groove 131, constructing a conductive grid. Specifically, nano silver ink is filled in the second groove 131 by scrapping technology, and is then sintered in the condition of 150 to make elemental silver of the nano silver ink be sintered into conductive wires. Herein, solid content of the silver ink is 35%, and the solvent is volatilized during sintering.

In the present embodiment, the step S140 also includes forming the second electrode lead 160 electrically connected to the second conductive layer 140.

Specifically, the second groove 131 includes a groove for receiving the second electrode lead 160. When filling conductive material into the second groove 131, the conductive material forms the second electrode lead 160 in the groove for receiving the second electrode lead 160.

In the present embodiment, the method of manufacturing the conductive film includes a step of forming a functional layer on the second surface for protection and anti-reflection.

Specifically, the functional layer includes a portion of hardening function and a portion of anti-reflection function. The portion of hardening function is formed by coating polymer coating with hardening function. The portion of anti-reflection function is titania cladding, or magnesium fluoride coating, or Calcium fluoride cladding, formed on the second surface.

Further, before the step S 130, the method of manufacturing the conductive film includes a step of painting adhesive on the first surface to form a tackifier layer.

Specifically, the tackifier layer is formed by adhesive painted on the first surface of the substrate 110, so the tackifier layer 170 plays the role of increasing adhesive strength between the matrix layer 130 and the substrate 110. Specifically in the present embodiment, the adhesive for forming the tackifier layer 170 can be one of epoxy resin, epoxy silane, and polyimide resin.

Comparing to the traditional method for manufacturing conductive film, the conductive film made by the above-mentioned method has two oppositely arranged conductive layers. Due to the capacitor formed between the first conductive layer 120 and the second conductive layer 140, when manufacturing a touch screen, a conductive film formed by method of manufacturing conductive film reduces the thickness of the touch screen and improving efficiency. In addition, the first groove 115 and the second groove 131 are defined by imprinting respectively on the substrate 110 and the matrix layer 130, and the first conductive layer 120 and the second conductive layer 140 are formed by filling conductive material respectively in the first groove 115 and the second groove 131, so no coating and etching are needed to form the first conductive layer 120 and the second layer 140. Therefore, the method of manufacturing conductive layer simplifies the process and saves material.

Although the present invention has been specifically and detailed described with reference to the above-mentioned embodiments thereof, it should not be understood as limitation of the scope of the present invention. What should be pointed out is, it is apparent to those skilled in the art that a variety of modifications and changes may be made without departing from the spirit of the present invention. Therefore, the scope of the present invention is intended to be defined by the appended claims

1. A conductive film, comprising:
a substrate comprising a first surface and a second surface opposite to the first surface;
a first conductive layer embedded in the substrate, a thickness of the first conductive layer being smaller than that of the substrate;
a matrix layer disposed on a first surface of the substrate, the matrix layer being made of a solidified jelly coating, a thickness of the matrix layer being smaller than the thickness of the substrate; and
a second conductive layer embedded in the matrix layer, a thickness of the second conductive layer being smaller than that of the matrix layer, the second conductive layer being insulated from the first conductive layer.

2. The conductive film of claim 1, wherein first grooves are defined in the first surface, second grooves are defined in a side of the matrix layer away from the substrate, and the first conductive layer and the second conductive layer are respectively received in the first grooves and the second grooves.

3. The conductive film of claim 2, wherein a distance between the first conductive layer and the second conductive layer is less than the thickness of the substrate, the thickness of the first conductive layer is no greater than a depth of the first groove, and the thickness of the second conductive layer is no greater than a depth of the second groove.

4. The conductive film of claim 1, wherein the first conductive layer and the second conductive layer are both conductive meshes consists of crisscross conductive wires, the conductive meshes comprise a plurality of grid units, the conductive wires of the first conductive layer are received in the first grooves, the conductive wires of the second conductive layer are received in the second grooves, and width of the conductive wires ranges between 500 nm and 5 μm.

5. The conductive film of claim 4, wherein the conductive wire is made of a material selected from the group consisting of metal, conductive polymer, grapheme, carbon nano-tube, and ITO.

6. The conductive film of claim 5, wherein the metal is selected from the group consisting of Au, Ag, Cu, Al, Ni, Zn, and an alloy of at least two of them.

7. The conductive film of claim 4, wherein the grid units are rhomboic, rectangle, parallelogram, or curved quadrilateral, and projection of centers of the grid units of the second conductive layer on the first conductive layer are spaced centers of the corresponding grid units of the first conductive layer.

8. The conductive film of claim 7, wherein distances between the projection of the center of the grid units of the second conductive layer on the first conductive layer and the centers of the corresponding grid units of the first conductive layer ranges from 1/3a to 2a/2, wherein “a” is a length of a side of one of the grid units.

9. The conductive film of claim 7, wherein projections of lines connecting centers of the grid units of the second conductive layer arranged in a direction on the first conductive layer is misaligned with lines connecting centers of the grid units of the first conductive layer in the same direction.

10. The conductive film of claim 1, further comprising:
a tackifier layer located between the substrate and the matrix layer, for adhering the matrix layer to the substrate; and
a functional attached to the second surface, for protection and anti-reflection.

11. The conductive film of claim 4, further comprising a first electrode lead cluster and a second electrode lead cluster, the first electrode lead cluster being embedded in the substrate and electrically connected to the first conductive layer, and the second electrode lead cluster being embedded in the matrix layer and electrically connected to the second conductive layer.

12. The conductive film of claim 11, wherein the first conductive layer comprises a plurality of mutually-insulated first gird strips, the second conductive layer comprises a plurality of mutually-insulated second gird strips, the first electrode lead cluster comprises a plurality of first leads respectively electrically connected to the first grid strips, and the second electrode lead cluster comprises a plurality of second leads respectively electrically connected to the second grid strips.

13. The conductive film of claim 12, wherein a first strip-like connecting portion is provided at the end of each of the first electrode leads near to the first conductive layer, the first connecting portion is thicker than other portion of the first electrode lead, a second strip-like connecting portion is provided at the end of each of the second electrode leads near to the second conductive layer, and the second connecting portion is thicker than other portion of the second electrode lead.

14. The conductive film of claim 13, wherein the first electrode lead and the second electrode lead consists of metal wires, which is crisscross to forming, and grid range of the first electrode lead and the second electrode lead is less than that of the first conductive layer and the second conductive layer.

15. The conductive film of claim 14, wherein a first electrode switching line is provided between each of the first electrode lead and the first conductive layer, a second electrode switching line is provided between each of the second electrode lead and the second conductive layer, the first switching line and the second switching line are consecutive fine conductive wires, the first switching line is connected to ends of at least two conductive wires of the first conductive layer and ends of at least two conductive wires of the first electrode lead, and the second switching line is connected to ends of at least two conductive wires of the second conductive layer and ends of at least two conductive wires of the second electrode lead.

16. A touch screen, comprising:
a glass panel; and
a conductive film comprising:
a substrate comprising a first surface and a second surface opposite to the first surface;
a first conductive layer embedded in the substrate, a thickness of the first conductive layer being smaller than that of the substrate;
a matrix layer disposed on a first surface of the substrate, the matrix layer being made of a solidified jelly coating, a thickness of the matrix layer being smaller than the thickness of the substrate; and
a second conductive layer embedded in the matrix layer, a thickness of the second conductive layer being smaller than that of the matrix layer, the second conductive layer being insulated from the first conductive layer.

17. A method of manufacturing touch screen, comprising the steps of:
providing a substrate, the substrate comprising a first surface and a second surface opposite to the first surface, and defining first grooves in the first surface;
filling conductive material into the first grooves to form a first conductive layer;
painting jelly on the first surface, solidifying the jelly to form a matrix layer, and defining a second groove in the matrix layer; and
filling conductive material into the second groove to form a second conductive layer.

18. The method of claim 17, wherein a first electrode lead cluster electrically connected to the first conductive layer is formed while filling conductive material into the first groove to form the first conductive layer, and a second electrode lead cluster electrically connected to the second conductive layer is formed while filling conductive material into the second groove to form the second conductive layer.

19. The method of claim 18, wherein the first conductive layer and the second conductive layer are conductive meshes consists of crisscross conductive wires, the conductive meshes comprise a plurality of grid units, the conductive wires of the first conductive layer are received in the first grooves, the conductive wires of the second conductive layer are received in the second groove, grid range of the first electrode lead and the second electrode lead is less than that of the first conductive layer and the second conductive layer.

20. The method of claim 19, wherein a first electrode switching line is provided between each of electrode lead of the first electrode lead cluster and the first conductive layer, a second electrode switching line is provided between each of electrode lead of the second electrode lead cluster and the second conductive layer, the first switching line and the second switching line are consecutive fine conductive wires, the first switching line is connected to ends of at least two conductive wires of the first conductive layer and ends of at least two conductive wires of the first electrode lead, and the second switching line is connected to ends of at least two conductive wires of the second conductive layer and ends of at least two conductive wires of the second electrode lead.
